(19) United States
(12) Patent Application Publication
(10) Pub. No.: US 2008/0067526 A1
(43) Pub. Date: Mar. 20, 2008

(54) Flexible circuits having improved reliability and thermal dissipation

(76) Inventor: Tong Fatt Chew, Penang (MY)

Correspondence Address: Kathy Manke;Avago Technologies Limited, 4380 Ziegler Road, Fort Collins, CO, 80525, US

(21) Appl. No.: 11/523,151

(22) Filed: Sep. 18, 2006

(51) Int. Cl. H01L 33/00; H01L 21/00

(52) U.S. Cl. 257/88; 438/24

(57) ABSTRACT

A flexible circuit that includes mounted electrical components, where bonding wires providing an electrical connection to the electrical components are aligned perpendicularly to the primary plane in which the flexible circuit bends and multiple redundant vias for electrical and thermal connections. The flexible circuit may include an array of light emitting diodes “(LEDs”) that are positioned length-wise in a flexile LED strip as well as flexible printed circuits having a plurality of electrical components attached thereto, where the electrical components may include LEDs. Methods of improving the reliability and thermal dissipation of a flexible circuit and producing a flexible circuit with re-aligned bonding wires and multiple vias for electrical and thermal connections are also provided.

### BACKGROUND OF THE INVENTION

The definition of a flexible circuit found in the IPC-T-50-F: Terms and Definitions for Interconnecting and Packaging Electronic Circuits, Revision F (June 1996), is: “A patterned arrangement of printed wiring utilizing flexible base material with or without flexible cover lay.” From this definition, there are a number of basic material elements that make up a flexible circuit: a dielectric substrate material, electrical conductors, a protective finish, and adhesives to bond the various materials together, with the adhesives being optional because there are alternatives to utilizing adhesives to bond the various materials together.

In general, the dielectric material may be either a polymide film, such as Kapton®, Apical®, or Upilex®, or a polyester. As for the electrical conductor, generally the material of choice is copper, which is available in several types. As for the flexible circuit itself, there are several generic variations, such as single-sided construction, double-sided construction, multilayer construction, and rigid-flex construction. In the case of rigid-flex circuits, rigid and flexible substrates may be laminated together, where the rigid substrate is typically FR-4, the material usually found in Printed Circuit Boards (“PCBs”). Together these materials form a basic flexible-circuit laminate that may be utilized as a simple wiring assembly or as a flexible final circuit assembly after mounting additional devices directly on the flexible-circuit laminate.

The advantages of flexible circuits are that they are significantly thinner and lighter than standard rigid PCBs, and may be utilized where space is at a premium, by bending the flexible circuit around corners or over itself in order to fit within a much smaller device enclosure than would be required for a rigid PCB. Flexible circuits have found use in many types of applications, and their design in based in part on the number of flex cycles required during its expected lifetime, from a few times during assembly, i.e., a one-time bending for fit or assembly (bend statically), to multiple flexes, i.e., repeated flexing over many cycles (bend dynamically).

With advances in Surface Mount Technology (“SMT”), there is the capability of mounting numerous other electrical components such as resistors, capacitors, current driver integrated circuits (“ICs”), controller and other ICs on a flexible-circuit laminate. Also included within such electrical components are light emitting diodes (“LEDs”). LEDs are, in general, miniature semiconductor devices that employ a form of electroluminescence resulting from the electronic excitation of a semiconductor material to produce visible light. Initially, the use of these devices was limited mainly to display functions on electronic appliances and the colors emitted were red and green. As the technology has improved, LEDs have become more powerful and are now available in a wide spectrum of colors, including blue and white.

With the capability of producing white light, there is now the possibility of using LEDs for illumination in place of incandescent and fluorescent lamps, including use in outdoor lighting applications. The advantages of using LEDs for illumination is that they are far more efficient than conventional lighting, are rugged and very compact, and can last much longer than incandescent or fluorescent light bulbs or lamps.

Given these properties of LEDs and the various colors that are now available, LEDs are finding usage in many more applications, including application that utilize flexible circuits. An example of a flexible circuit is the flexible LED array (or “flex-LED”), which is an array of LEDs aligned length-wise, where each LED in the flex-LED is electrically connected to the adjacent LEDs, thus completing an electrical connection whereby each LED in the flex-LED has a bias voltage. The flex-LED may also contain an encapsulant that covers each LED, which may be any encapsulant used in an LED, such as an optically clear epoxy resin or silicone system, and a flexible substrate on which the LEDs are attached. The flex-LED may also be enclosed in a waterproof/weatherproof, transparent casing, which may be made from any polymeric transparent material. The flex-LED may be commercially available in various standardized lengths of a light strip such that these light strips may be cut or drilled so that the user can connect multiple light strips and adapt the flex-LED to his particular installation requirements.

In FIG. 1A, a schematic diagram illustrating an example of a section of a known flex-LED 100 along its length is shown. Flex-LED 100 is a section of a flex-LED strip that may be of a standard length, that is, flex-LED 100 shows only a portion of a longer strip that contains a plurality of LEDs positioned equidistantly throughout the flex-LED strip. This flex-LED strip may be cut to obtain the desired length and multiple strips may then be joined together using standardized connectors (not shown).

The flex-LED 100 may include a substrate 102, which may be flexible-circuit laminate that includes a flexible dielectric and electrical conductors. Attached to the substrate 102 is a plurality of LEDs 104. A bonding wire 106 may provide one of the two electrical connections required for each of the LEDs 104, for example, an anode connection. A cathode connection may then be located on the bottom surface of each LED 104, in the form of backside metallization (not shown), which may be implemented by attaching a conducting material to the bottom of each LED 104. The entire assembly of the LEDs 104 and the substrate 102 may then be encapsulated in an encapsulant 108 applied to the surface of the assembly. Additionally, the entire assembly including the encapsulant 108 may also be enclosed in a transparent casing (not shown).

FIG. 1B shows a cross-sectional side view of the flex-LED 100 across its width. In FIG. 1B, the flex-LED 100 includes an LED 104 attached to a substrate 102. This package may be covered by an encapsulant 108. The bonding wire 106 completes the electrical connection to an electrical conductor (not shown). In FIG. 1A, the arrows 112 indicate the primary direction of the flexing of the flex-LED 100. As the flex-LED 100 flexes in the direction of the arrows 112, the bonding wires 106 will tend to stretch, and with repeated flexing of the flex-LED 100, there is an increased possibility of the bonding wires 106 breaking or failing.

In FIG. 1C, a schematic diagram illustrating another example of a section of a known flex-LED 100 along its length is shown. As in FIG. 1A, flex-LED 100 is a section of a flex-LED strip that may be of a standard length, that is, flex-LED 100 shows only a portion of a longer strip that contains a plurality of LEDs positioned equidistantly throughout the flex-LED strip. The flex-LED 100 may include a substrate 102 that may include a flexible dielectric and electrical conductors. Attached to the substrate 102 is a plurality of LEDs 104. A bonding wire 106 may provide one of the two electrical connections required for each of the LEDs 104, for example, an anode connection. The other connection, in this case, a cathode connection for each LED 104, may then be provided by bonding wire 110. The entire assembly of the LEDs 104 and the substrate 102 may then be encapsulated in an encapsulant 108 applied to the surface of the assembly. Additionally, the entire assembly including the encapsulant 108 may also be enclosed in a transparent casing (not shown).

The arrows 112 indicate the primary direction of the flexing of the flex-LED 100. As the flex-LED 100 flexes in the direction of the arrows 112, the bonding wires 106 and 108 will tend to stretch, and with repeated flexing of the flex-LED 100, there is an increased possibility of the bonding wires 106 and 110 breaking or failing.

A similar problem in both flexible and rigid circuits is present with respect to vias. In general, vias are holes drilled through a flexible circuit or a PCB, which are plated and then filled with a polymer, which may be conductive or non-conductive, to provide a vertical electrical or thermal connection between different layers of the flexible circuit or PCB. In FIG. 2, a schematic diagram illustrating an example of a section of a known flexible circuit is shown. The flexible circuit 200 may include a dielectric 202 laminated with a top conductor 204 on the top and a bottom conductor 206 on the bottom. The flexible circuit 200 may also include a via 212, which may be plated 210 and filled with a filler 208.

When the flexible circuit 200 flexes in the direction of the arrows 214, the filler 212 may tend to separate from the edge of the via 208, thus creating cracks or fissures within the area denoted by the circle 216. With repeated flexing of the flexible circuit 200, there is an increased possibility of the cracks appearing in the flexible circuit 200, which may eventually cause its failure. In particular, if the via is utilized for thermal dissipation, the tendency for such cracks to appear may be even more likely.

In FIG. 3, a schematic diagram illustrating an example of a section of a known flexible printed circuit (“FPC”) 300 is shown. FPC 300 shows a side view of a section of a flexible circuit that may be of a standard length, that is, FPC 300 shows only a portion of a longer strip containing an array bonded to a thin, flexible dielectric. A dielectric 302 is positioned between a top metal layer 304 and a bottom metal layer 306. Attached to the top metal layer 304 may be a component 308, which may be, as an example, an LED. A bonding wire 310 may provide one of the two electrical connections required for the component 308, for example, an anode connection. A cathode connection may then be located on the bottom surface of the component 308, in the form of backside metallization (not shown), which may be implemented by attaching a conducting material to the bottom of component 308. The entire assembly may then be covered by an encapsulant 312.

In addition to the problems caused by the repeated flexing of the flex-LEDs and flexible circuits, these devices also have the problem of thermal dissipation. In particular, LEDs generate heat and in the LED arrays found in flex circuits, this problem is even more critical. In general, LED devices are commonly prone to damage caused by buildup of heat generated from within the devices, as well as heat from sunlight in the case of outside lighting applications. Although metallized LED substrates are useful design elements that can be incorporated into LED devices and may serve to dissipate heat, these elements are often inadequate to maintain reasonably moderate temperatures in the devices. Excessive heat buildup can nevertheless cause deterioration of the materials used in the LED devices, such as encapsulants for the LED. When LEDS are attached to flexible-circuit laminates that may also include other electrical components, the heat dissipation problems are greatly increased.

Consequently, there is a continuing need to improve the design of flexible circuits and flex-LEDs to reduce damage to these devices caused by repeated flexing or sharp bending, which may occur during manufacture, testing, installation, or operation, as well as to improve the thermal dissipation properties of these devices.

### SUMMARY

In general, a system and a method of improving the reliability of flexible circuits and their thermal dissipation properties by re-aligning the wire bonding in these devices and by adding and repositioning redundant vias in the flexible-circuit laminate utilized for thermal dissipation are disclosed. In a flex-LED device, the wire bonding for each LED is aligned perpendicular to the direction of primary flexing, i.e., perpendicular to the length-wise axis of the flex-LED. Additionally, a flexible circuit may include multiple vias utilized for thermal dissipation positioned near a component attached to the flexible-circuit laminate to improve thermal dissipation

In another example of an implementation, an electrical connection may be made without a via, by utilizing an electrical connection on the top surface of the flexible-circuit laminate.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1A shows a cross-sectional side view illustrating an example of an implementation of a known flex-LED.

FIG. 1B shows a cross-sectional end view of the known flex-LED device shown in FIG. 1A.

FIG. 1C shows a cross-sectional side view illustrating another example of an implementation of a known flex-LED with two bonding wires per LED.

FIG. 2 shows a cross-sectional side view illustrating an example of a known implementation of a printed circuit board.

FIG. 3 shows a cross-sectional side view illustrating an example of a known flexible circuit.

FIG. 4A shows a cross-sectional side view illustrating an example of an implementation of a flex-LED in accordance with the invention.

FIG. 4B shows a cross-sectional end view of the flex-LED shown in FIG. 4A.

FIG. 4C shows a cross-sectional end view of the flex-LED with a filled via.

FIG. 5A shows a perspective view of a section of an example of an implementation of a flexible circuit having multiple vias.

FIG. 5B shows a perspective view of a section of another example of an implementation of a flexible circuit having multiple vias.

FIG. 6 shows a cross-sectional side view illustrating an example of an implementation of a flexible circuit having multiple vias for thermal and electrical connections.

FIG. 7A shows a perspective view illustrating an example of an implementation of a flexible circuit having multiple vias.

FIG. 7B shows a top view of an example of a via layout for the flexible circuit shown in FIG. 7A.

FIG. 8 shows a perspective view illustrating another example of an implementation of a flexible circuit without vias.

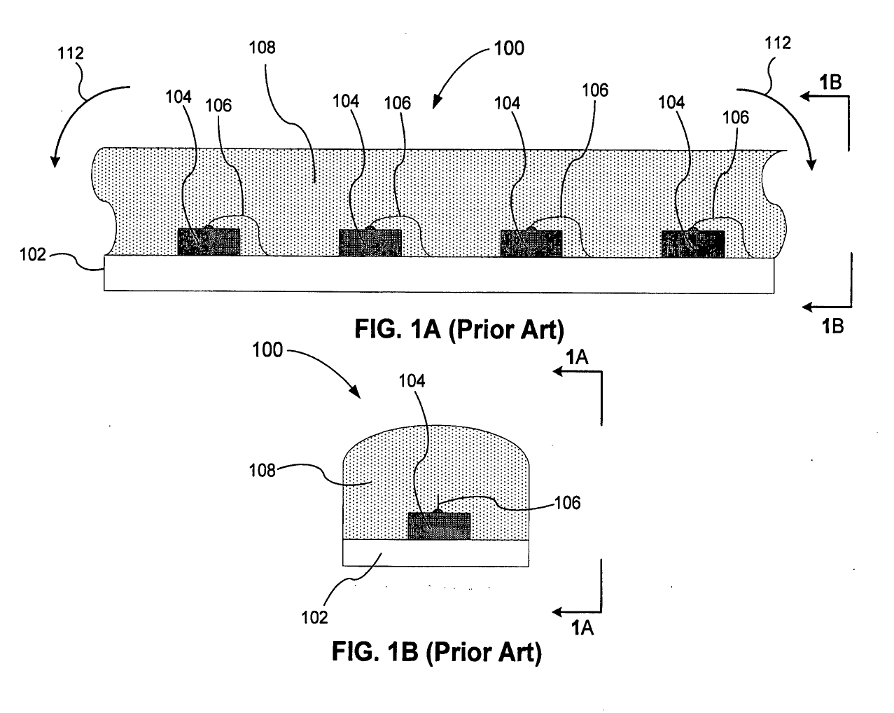

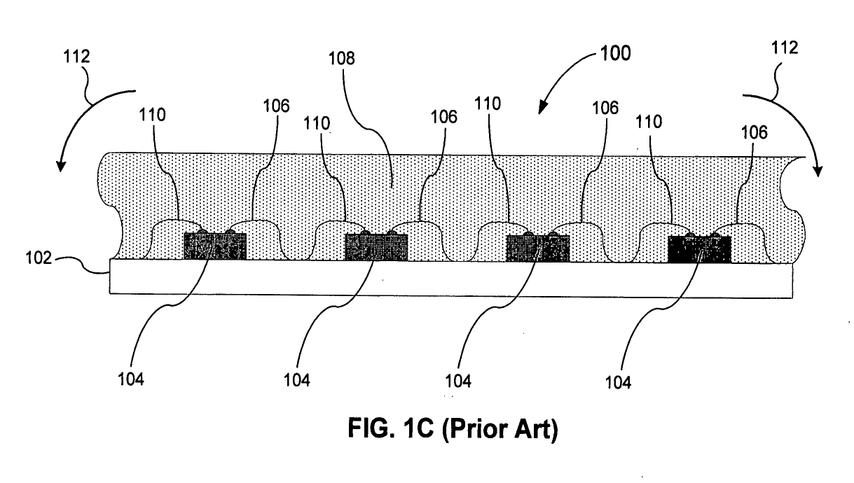

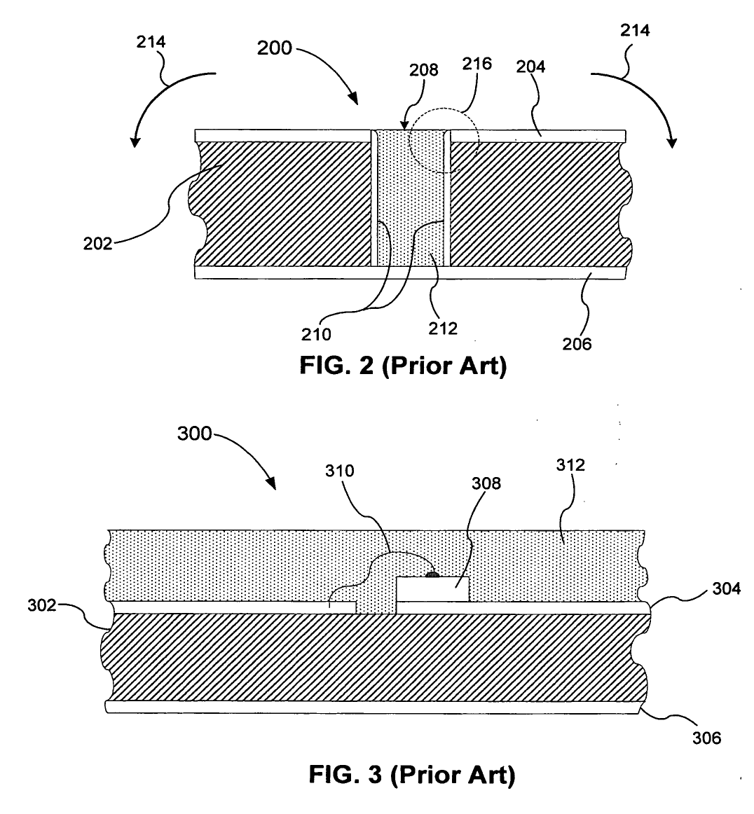

### DETAILED DESCRIPTION

In the following description of examples of implementations, reference is made to the accompanying drawings that form a part hereof, and which show, by way of illustration, specific implementations of the invention that may be utilized. Other implementations may be utilized and structural changes may be made without departing from the scope of the present invention.

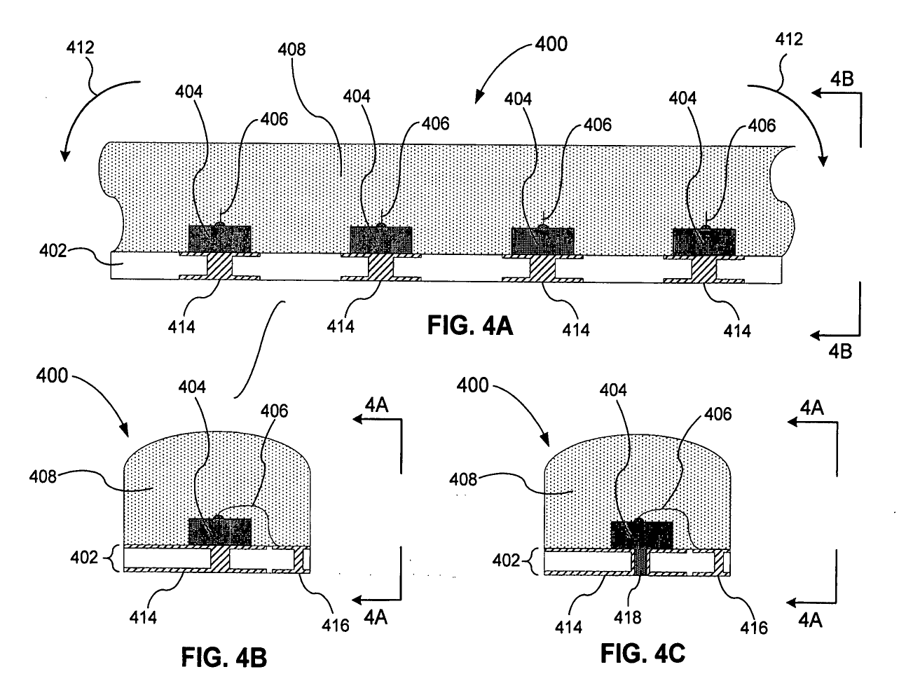

In general, a system and a method of improving the thermal dissipation properties of flexible circuits by adding and repositioning vias utilized for thermal dissipation and the reliability of these devices by adding multiple electrical vias and by re-aligning the wire bonding in these devices is disclosed. Turning to FIG. 4A, a cross-sectional side view illustrating an example of an implementation of a flex-LED 400 in accordance with the invention is shown. The flex-LED 400 may include a substrate 402 that may include a flexible dielectric and electrical conductors. Attached to the substrate 402 is a plurality of LEDs 404. A bonding wire 406 may provide one of the two electrical connections required for each of the LEDs 404, for example, an anode connection. A cathode connection may then be located on the bottom surface of the LED 404, in the form of backside metallization (not shown), which may be implemented by attaching a conducting material to the bottom of each LED 404 and mounting LED 404 on the electrode and thermal pad 414.

In FIG. 4A, the wire bonding wire 406 for each LED 404 is aligned perpendicularly to the direction of primary flexing, i.e., perpendicular to the length-wise axis of the flex-LED 400. In another embodiment, a two-wire bond LED chip may be implemented where both anode and cathode electrode contacts are on the same side of the LED chip, i.e., the top surface. Where there are two bond wires per LED chip, both bond wires are positioned to be substantially perpendicular to the longitudinal axis of the flex strip.

The entire assembly may be encapsulated in an encapsulant 408. In another embodiment, the encapsulant and the assembly may be enclosed in a transparent casing (not shown). FIG. 4B shows a cross-sectional end view of the flex-LED 400 across its width. In FIG. 4B, the flex-LED 400 includes an LED 404 attached to a substrate 402. This package may be encapsulated in an encapsulant 408. The bonding wire 406 completes an electrical connection to a second electrode 416 in the substrate 402. The other electrical connection is to a first electrode 414, which may be a fully-filled via, e.g., a blind via, or a filled via, i.e., a via created by a hole drilled through the substrate 402, then plated with a conductive metal such as copper, silver, etc., and filled with a resin/plug material.

In FIG. 4A, the arrows 412 indicate the primary direction of the flexing of the flex-LED 400. In FIG. 4B, the bonding wire 406 is affixed to the LED 406 and connected to the second electrode 416 in an orientation that is perpendicular to the plane of the direction of primary flexing, that is, the plane defined by the arrows 412. Thus, any flexing in this plane will not effect or cause any stress on the bonding wire 406.

In FIG. 4C, a cross-sectional end view illustrating another example of an implementation of the flex-LED device shown in FIG. 4A is shown. As in FIG. 4B, the bonding wire 406 is affixed to the LED 404 and connected to the second electrode 416 in an orientation that is perpendicular to the plane of the direction of primary flexing, that is, the plane defined by the arrows 412. The connection to the first electrode 414 is made through via 418, which is positioned under the LED 404. Thus, any flexing in this plane will not effect or cause any stress on the bonding wire 406 or the via 418.

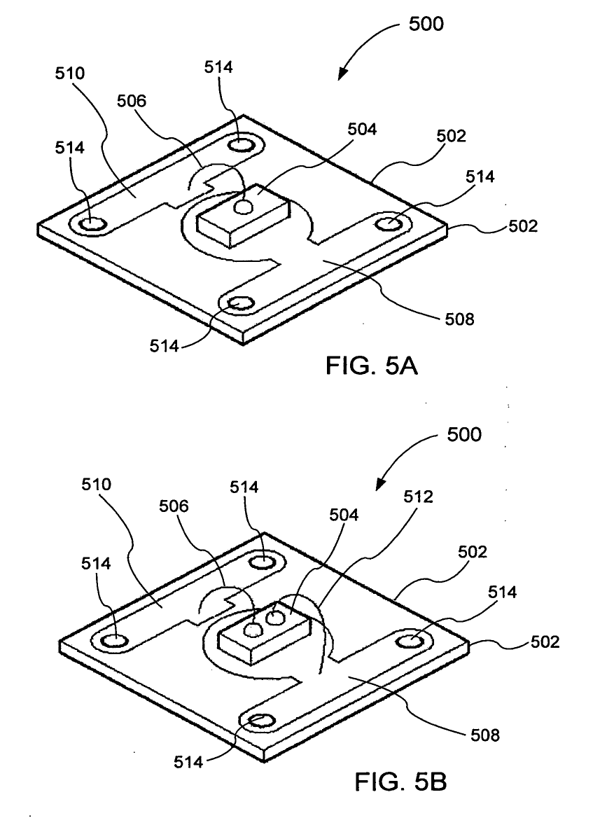

In FIG. 5A, a perspective view of a section illustrating an example of a flexible circuit 500 having multiple vias in accordance with the invention is shown. Flexible circuit 500 may include a substrate 502 on which a component 504, such as an LED, may be attached. A bonding wire 506 may provide an electrical connection for the component 504 to an anode pad 510, with a connection to a cathode pad 508 made on the bottom surface of the component 504 utilizing a backside metallization (not shown).

Flexible circuit 500 may also include 4 vias 514 that may be positioned near the LED attached to the flexible circuit. As an example, the flexible circuit may include multiple, redundant vias 514 utilized for thermal dissipation positioned near the component 504 at approximately equal distances therefrom. With this configuration of multiple thermal vias utilized for thermal dissipation, at least two of these vias will not be subjected to stress caused by repeated flexing or sharp bending of the flexible circuit of which it is a part.

In FIG. 5B, a perspective view of a section illustrating another example of a flexible circuit 500 having multiple vias in accordance with the invention is shown. A component 504, such as an LED, may be attached to a substrate 502, with a bonding wire 506 providing an electrical connection for the component 504 to an anode pad 510, and a bonding wire 512 providing an electrical a connection to a cathode pad 508. As in FIG. 5A, the flexible circuit 500 may include multiple, redundant vias 514 utilized for thermal dissipation positioned near the component 504 at approximately equal distances therefrom, thus allowing to avoid the stress caused by repeated flexing or sharp bending of the flexible circuit of which it is a part.

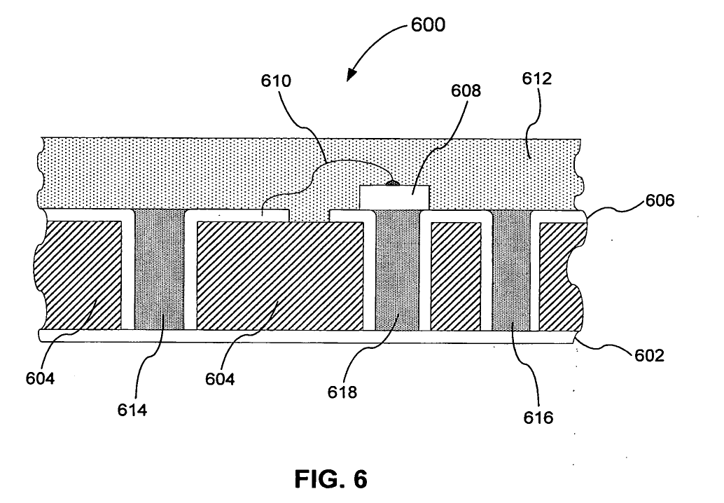

Turning to FIG. 6, a cross-sectional side view illustrating an example of an implementation of a flexible circuit having multiple vias for thermal and electrical connections is shown. Flexible printed circuit (“FPC”) 600 may include a dielectric 604 that is positioned between a top metal layer 606 and a bottom metal layer 602. Attached to the top metal layer 606 may be a component 608, which may be, as an example, an LED. A bonding wire 610 may provide one of the two electrical connections required for the component 608, for example, an anode connection. A cathode connection may then be located on the bottom surface of the component 608 in the form of backside metallization (not shown), which may be implemented by attaching a conducting material to the bottom of component 608. The entire assembly may then be covered by an encapsulant 612.

FPC 600 may also include vias 614 and 616 for thermal dissipation that pass through the dielectric 604 and dissipate heat from the component 608 through the top layer 606 to the bottom layer 602, which may be an aluminum or copper plate. For the other electrical connection, i.e., the cathode connection in this example, the FPC 600 may include a blind via 618 under the component 608 that provides an electrical connection to the bottom layer 602.

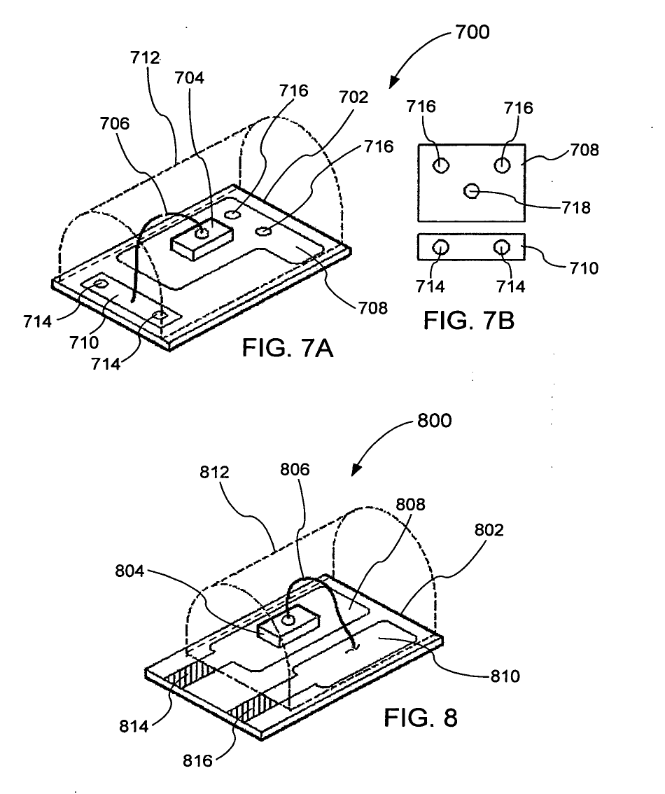

In FIG. 7A, a perspective view illustrating an example of another implementation of a flex-circuit having multiple vias is shown. Flex-circuit 700 may include a substrate 702 on which a component 704, such as an LED, may be attached. A bonding wire 706 may provide an electrical connection for the component 704 to an anode pad 710, with a connection to a cathode pad 708 made on the bottom surface of the component 704 utilizing a backside metallization (not shown). In one embodiment, the substrate 702 and the LED 704 may be encapsulated with encapsulant 712. In another embodiment, the substrate 702 may be enclosed within a transparent casing (not shown), which may then be filled with an encapsulant.

Flex-circuit 700 may include multiple vias drilled through the substrate 702, such as vias 714, which may be in electrical connection with the anode pad 710, and vias 716, which may be in electrical connection with the cathode pad 708. These vias may be also configured to provide a path for thermal dissipation from the component 708 by being filled with a thermally conductive material.

Flex-circuit 700 may further include a blind via (not shown) located under the component 704 that provides an electrical connection from the component 704 to a ground plane (not shown) below the substrate 702. FIG. 7B shows a top view illustrating an example of a via layout for the flex-circuit 700 shown in FIG. 7A. Vias 714 and 716 may be configured for thermal connections, while blind via 718 may be configured for an electrical connection for the component (not shown) attached to the cathode post 708.

In FIG. 8, a perspective view illustrating an example of an implementation of a flex-circuit without vias is shown. Flex-circuit 800 may include a substrate 802 on which a component 804, such as an LED, may be attached. A bonding wire 806 may provide an electrical connection for the component 804 to an anode pad 810, with a connection to a cathode pad 808 made on the bottom surface of the component 804 utilizing a backside metallization (not shown). In a first embodiment, the substrate 802 and the LED 804 may be encapsulated with encapsulant 812. In a second embodiment, the substrate 802 and the LED 804 may be enclosed within a transparent casing (not shown), which may then be filled with an encapsulant.

In flex-circuit 800, the electrical connection is taken out of the flex-circuit 800 by external terminations 814 and 816 of electrical terminals without utilizing vias or solder pads. The electrical terminals may be positioned so that they are taken out of the flex-circuit 800 on the same side of the flex-circuit 800.

While the foregoing descriptions refer to the use of an LED as the component attached to a flex-LED and a flexible circuit, the subject matter is not limited to LEDs as the component utilized in a flexible circuit or to flex-LEDs or flexible printed circuits as the substrate. Any electronic component and any type of substrate that could benefit from the functionality provided by the components described above may be implemented as the elements of the invention. The flexible circuits described above applies to thin laminated circuits having low thickness compared to conventional PCBs and may or may not be subject to being flexed or bended many multiple times in end applications. In end applications, it may be in a final state or shape of being bent, or curved to conform to a particular shape with straight sections, curved sections or combination thereof.

Moreover, it will be understood that the foregoing description of numerous implementations has been presented for purposes of illustration and description. It is not exhaustive and does not limit the claimed inventions to the precise forms disclosed. Modifications and variations are possible in light of the above description or may be acquired from practicing the invention. The claims and their equivalents define the scope of the invention.

What is claimed:

1. A flexible circuit capable of being conformed to a desired configuration, the flexible circuit comprising:
a flexible substrate capable of being flexed in at least one direction;
a plurality of light-emitting diodes (“LEDs”) that is attached to the flexible substrate; and
at least one bonding wire completing an electrical connection for each of the plurality of LEDs, wherein the at least one bonding wire is configured perpendicularly to the direction of the flexing of the flexible circuit.

2. The flexible circuit of claim 1, wherein the flexible substrate is a flexible-circuit laminate that includes a flexible dielectric, a first electrical conductor, and a second electrical conductor.

3. The flexible circuit of claim 2, wherein at least one electrical component selected from the group consisting of resistors, capacitors, driver Integrated Circuits (“ICs”), and controller ICs is attached to the flexible substrate.

4. The flexible circuit of claim 2, wherein the plurality of LEDs is attached length-wise in an LED strip.

5. The flexible circuit of claim 4, further including a plurality of redundant vias for each LED fabricated in the LED strip capable of providing an electrical or thermal connection to the flexible circuit.

6. The flexible circuit of claim 5, wherein the vias are positioned relative to each LED outside a plane defined by the direction in which the flexible circuit may be flexed.

7. The flexible circuit of claim 2, wherein the flexible substrate is configured for bending statically.

8. The flexible circuit of claim 2, wherein the flexible substrate is configured for bending dynamically.

9. A method of improving the reliability and thermal dissipation of a flexible circuit having a plurality of LEDs, the method comprising:
wire bonding at least one electrical connection for each of the plurality of LEDs, wherein a bonding wire is aligned perpendicularly to a direction in which the flexible circuit may be flexed; and
providing at least one via for thermal dissipation to each of the plurality of LEDs, wherein the at least one via is positioned on the flexible circuit outside of a plane defined by the direction in which the flexible circuit may be flexed.

10. The method of claim 9, wherein the plurality of LEDs are electrically connected length-wise in an LED strip.

11. The method of claim 10, further including the step of providing an electrical connection at a base of each of the plurality of the LEDs utilizing a blind via.

12. The method of claim 10, further including the step of providing at least one other via for thermal dissipation to each of the plurality of LEDs.

13. A method of producing a flexible circuit having a plurality of LEDs, the method comprising:
attaching the plurality of LEDs to a flexible circuit substrate;
wire bonding at least one electrical connection for each of the plurality of LEDs using a bonding wire;
aligning the bonding wires perpendicular to a direction in which the flexible circuit may be flexed;
providing the flexible circuit substrate with at least one via for thermal dissipation for each of the plurality of LEDs; and
positioning the at least one via on the flexible circuit substrate outside of a plane defined by the direction in which the flexible circuit may be flexed.

14. The method of claim 13, wherein the flexible circuit substrate is a flexible-circuit laminate that includes a flexible dielectric, a first electrical conductor, and a second electrical conductor.

15. The method of claim 14, further including the step of attaching at least one electrical component selected from the group consisting of resistors, capacitors, driver Integrated Circuits (“ICs”), and controller ICs to the flexible circuit substrate.

16. The method of claim 15, wherein the attaching of the at least one electrical component is implemented using Surface Mount Technology (“SMT”).

17. The method of claim 14, wherein the plurality of LEDs are electrically connected length-wise and form an LED strip with the flexible circuit substrate.

18. The method of claim 17, further including the step of providing an electrical connection at a base of each of the plurality of the LEDs utilizing a blind via.

19. The method of claim 17, wherein the step of providing at least one via for thermal dissipation further includes providing at least one other via to each of the plurality of LEDs.

20. The method of claim 17, wherein the flexible circuit substrate is configured for bending statically or for bending dynamically.
